(19) United States
(12) Patent Application Publication
(10) Pub. No.: US 2024/0071713 A1
(43) Pub. Date: Feb. 29, 2024

(54) DUAL FOCUS SOLUTON FOR SEM METROLOGY TOOLS

(71) Applicant: ASML Netherlands B.V., Veldhoven (NL)

(72) Inventors: Niels Johannes Maria BOSCH, Eindhoven (NL); Xu WANG, San Jose, CA (US); Peter Paul HEMPENIUS, Eindhoven (NL); Yongqiang WANG, Fremont, CA (US); Hans BUTLER, Best (NL); Youjin WANG, Milpitas, CA (US); Jasper Hendrik GRASMAN, Waalre (NL); Jianzi SUI, Fremont, CA (US); Tianming CHEN, San Jose, CA (US); Aimin WU, Milpitas, CA (US)

(73) Assignee: ASML Netherlands B.V., Veldhoven (NL)

(21) Appl. No.: 18/270,707

(22) PCT Filed: Dec. 9, 2021
(86) PCT No.: PCT/EP2021/085051

§ 371 Date: Jun. 30, 2023

Related U.S. Application Data
(60) Provisional application No. 63/285,275, filed on Dec. 2, 2021.
(60) Provisional application No. 63/132,198, filed on Dec. 30, 2020.

(51) Int. Cl. H01J 37/20

(52) U.S. Cl. CPC H01J 37/20; H01J 37/28; H01J 2237/20235

(57) ABSTRACT

There is provided a charged particle apparatus comprising: a particle beam generator, optics, a first and a second positioning device, both configured for positioning the substrate relative to the particle beam generator along its optical axis, and a controller configured for switching between a first operational mode and a second operational mode. The apparatus is configured, when operating in the first operational mode, for irradiating the substrate by the particle beam at a first landing energy of the particle beam and, when operating in the second operational mode, for irradiating the substrate at a second, different landing energy. When operating in the first operational mode, the second positioning device is configured to position the substrate relative to the particle beam generator at a first focus position of the particle beam and in the second operational mode, to position the substrate at a second, different focus position.

### CROSS-REFERENCE TO RELATED APPLICATIONS

This application claims priority of U.S. application 63/132,198 which was filed on Dec. 30, 2020 and U.S. application 63/285,275 which was filed on Dec. 2, 2021 which are incorporated herein in its entirety by reference.

### FIELD OF THE INVENTION

The present description relates to an electron beam (e-beam) inspection apparatus configured to inspect a specimen such as semiconductor device.

### BACKGROUND

In the semiconductor processes, defects are inevitably generated. Such defects may impact device performance even up to failure. Device yield may thus be impacted, resulting in increased costs. In order to control semiconductor process yield, defect monitoring is important. One tool useful in defect monitoring is an SEM (Scanning Electron Microscope) apparatus which scans a target portion of a specimen using one or more beams of electrons. An SEM is an example of a particle beam apparatus.

It may be desirable to provide a new particle beam apparatus, which may be used as part of an inspection apparatus, and which at least partially addresses one or more problems associated with prior art SEM apparatus.

### SUMMARY

According to a first embodiment, there is provided a charged particle apparatus comprising: a particle beam generator configured for generating a particle beam to be irradiated onto a substrate; optics configured for focusing the particle beam; a first positioning device configured for positioning the substrate relative to the particle beam generator along an optical axis of the particle beam generator over a first range of movement; a second positioning device configured for positioning the substrate relative to the particle beam generator along the optical axis; and a controller configured for switching between a first operational mode and a second operational mode of the apparatus. The apparatus is configured, when operating in the first operational mode, for irradiating the substrate by the particle beam at a first landing energy of the particle beam. The apparatus is further configured, when operating in the second operational mode, for irradiating the substrate with the particle beam at a second landing energy of the particle beam. The second landing energy is different from the first landing energy. When operating in the first operational mode, the second positioning device is configured to position the substrate relative to the particle beam generator at a first focus position of the particle beam. When operating in the second operational mode, the second positioning device is configured to position the substrate relative to the particle beam generator at a second focus position of the particle beam. The second focus position is at a distance from the first focus position. The distance is larger than the first range of movement.

### BRIEF DESCRIPTION OF THE DRAWINGS

Embodiments will now be described, by way of example, with reference to the accompanying drawings in which:

FIGS. 1A and 1B show schematic illustrations of an e-beam inspection apparatus being an embodiment of an e-beam inspection apparatus;

FIGS. 2A and 2B show schematic illustrations of an electron optical system as may be applied in embodiments of the charged particle apparatus;

FIG. 3 schematically shows a possible control architecture of the e-beam inspection apparatus according to an embodiment;

FIG. 4 schematically shows an e-beam inspection apparatus having focus height differences due to varying landing energies of electron beam;

FIG. 5 shows a schematic illustration of an e-beam inspection apparatus according to the first embodiment; and

FIG. 6 show a schematic illustration of an e-beam inspection apparatus according to the second embodiment.

FIG. 7 shows a schematic illustration of an e-beam inspection apparatus according to the third embodiment; and

FIG. 8 show a schematic illustration of an e-beam inspection apparatus according to the forth embodiment.

### DETAILED DESCRIPTION

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. These embodiments may, however, may be embodied in many alternate forms and should not be construed as limited to only the embodiments set forth herein.

As used herein, the term “wafer” generally refers to substrates formed of a semiconductor or non-semiconductor material. Examples of such a semiconductor or non-semiconductor material include, but are not limited to, monocrystalline silicon, gallium arsenide, and indium phosphide. Such substrates may be commonly found and/or processed in semiconductor fabrication facilities.

The term “substrate” may be a wafer (as above) or a glass or quartz substrate, and may also include a patterning device such as a reticle, which may also be called as a “mask”.

In this document, the word “axial” means “in the optical axis direction of an apparatus, column or a device such as a lens”, while the word “radial” means “in a direction perpendicular to the optical axis”. Usually, the optical axis starts from the cathode and ends at specimen. The optical axis always refers to z-axis in all drawings.

The term, crossover, refers to a point where the electron beam is focused.

The term, virtual source, means the electron beam emitted from the cathode can be traced back to a “virtual” source.

The inspection apparatus according to the embodiments in this document relates to a charged particle source, especially to an e-beam source which can be applied to a SEM, an e-beam inspection apparatus, or an EBDW. The e-beam source, in this art, may also be referred to as an e-gun (Electron Gun) or electron beam generator.

With respect to the drawings, it is noted that the figures are not drawn to scale. In particular, the scale of some of the elements of the figures may be greatly exaggerated to emphasize characteristics of the elements. It is also noted that the figures are not drawn to the same scale. Elements shown in more than one figure that may be similarly configured have been indicated using the same reference numerals. Within the following description of the drawings the same or like reference numbers refer to the same or like components or entities, and only the differences with respect to the individual embodiments are described.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives embodiments.

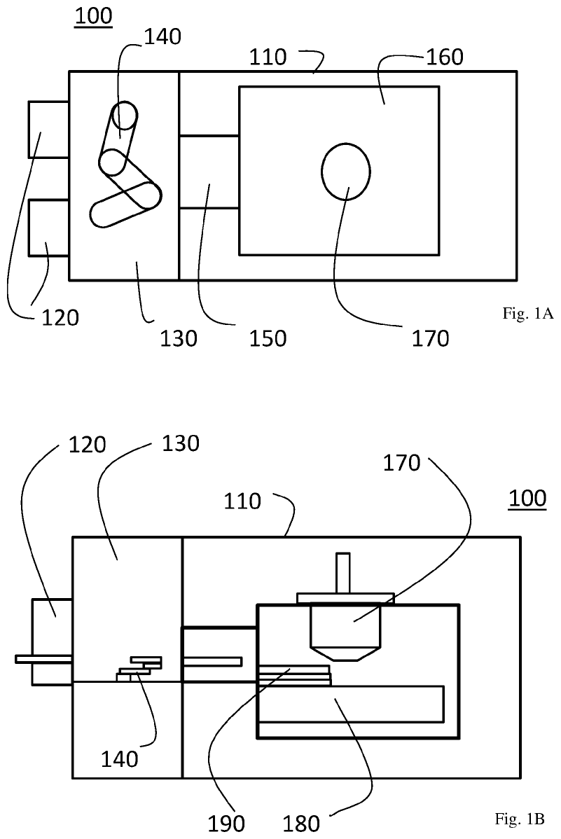

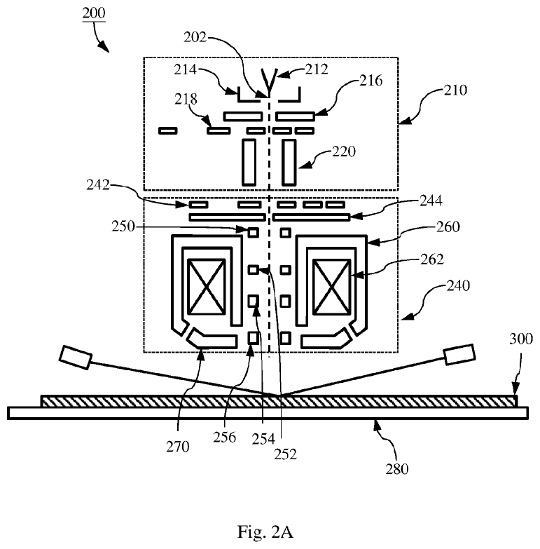

FIGS. 1A and 1B schematically depict a top view and a cross-sectional view of an electron beam (e-beam) inspection (EBI) apparatus 100 according to an embodiment. The embodiment as shown comprises an enclosure 110, a pair of load ports 120 serving as an interface to receive objects to be examined and to output objects that have been examined. The embodiment as shown further comprises an object transfer system, referred as an EFEM, equipment front end module 130, that is configured to handle and/or transport the objects to and from the load ports. In the embodiment as shown, the EFEM 130 comprises a handler robot 140 configured to transport objects between the load ports and a load lock 150 of the EBI apparatus 100. The load lock 150 is an interface between atmospheric conditions occurring outside the enclosure 110 and in the EFEM and the vacuum conditions occurring in a vacuum chamber 160, also referred to as chamber, of the EBI apparatus 100. In the embodiment as shown, the vacuum chamber 160 comprises an electron optics system 170 configured to project an e-beam onto an object to be inspected, e.g. a semiconductor substrate or wafer. The EBI apparatus 100 further comprises a positioning device 180 that is configured to displace the object 190 relative to the e-beam generated by the electron optics system 170. In an embodiment, the positioning device 180 is at least partly arranged within the vacuum chamber 160.

In an embodiment, the positioning device may comprise a cascaded arrangement of multiple positioners such an XY-stage for positioning the object in a substantially horizontal plane, and a Z-stage for positioning the object in the vertical direction.

In an embodiment, the positioning device may comprise a combination of a coarse positioner, configured to provide a coarse positioning of the object over comparatively large distances and a fine positioner, configured to provide a fine positioning of the object over comparatively small distances.

In an embodiment, the positioning device 180 further comprises an object table for holding the object during the inspection process performed by the EBI apparatus 100. In such embodiment, the object 190 may be clamped onto the object table by means of a clamp such as an electrostatic clamp or vacuum clamp. Such a clamp may be integrated in the object table.

The positioning device 180 may comprises a first positioner for positioning the object table and a second positioner for positioning the first positioner and the object table.

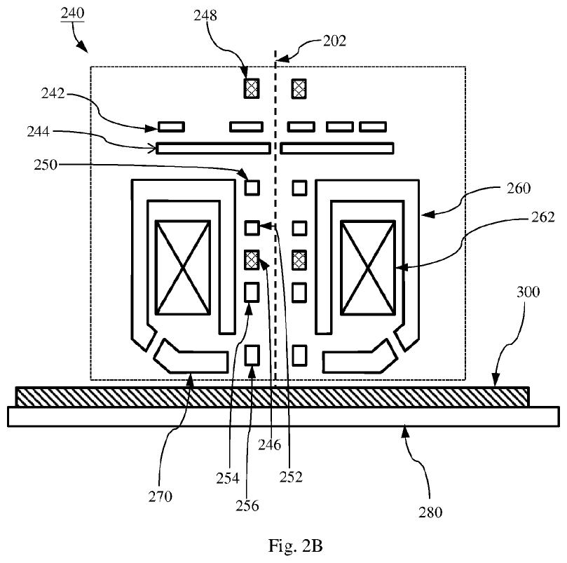

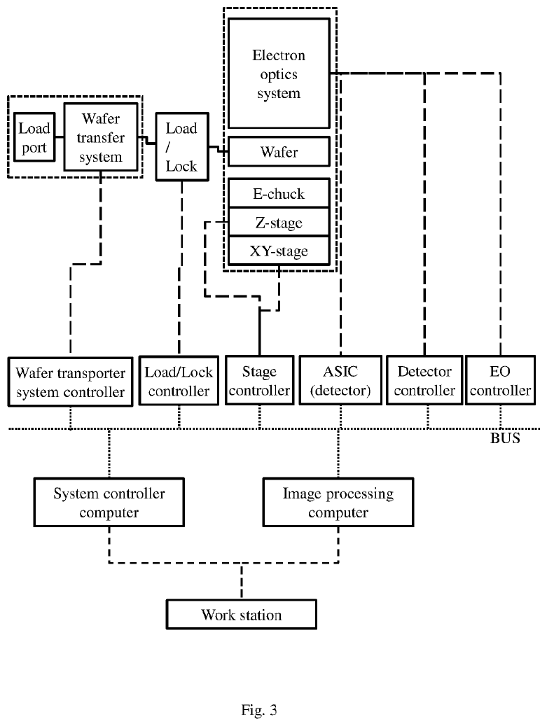

FIG. 2A schematically shows a schematic illustration of an embodiment of an electron optics system 200 as may be applied in e-beam inspection apparatus 100 or system according to the present embodiments in this document. The electron optics system 200 comprises an e-beam source, referred to as the electron gun 210 and an imaging system 240.

The electron gun 210 comprises an electron source 212, suppressor 214, an anode 216, a set of apertures 218, and a condenser 220. The electron source 212 can be a Schottky emitter. More specifically, the electron source 212 e.g. includes a ceramic substrate, two electrodes, a tungsten filament, and a tungsten pin (details not shown). The two electrodes are fixed in parallel to the ceramic substrate, and the other sides of the two electrodes are respectively connected to two ends of the tungsten filament. The tungsten filament is slightly bended to form a tip for placing the tungsten pin. Next, a ZrO2 is coated on the surface of the tungsten pin, and is heated to 1300° C. so as to be melted and cover the tungsten pin but uncover the pinpoint of the tungsten pin. The melted ZrO2 lowers the work function of the tungsten and decreases the energy barrier of the emitted electron, and thus the electron beam 202 is emitted more efficiently. Then, by applying negative electricity to the suppressor 214, the electron beam 202 is suppressed. Accordingly, the electron beam having the large spread angle is suppressed to the primary electron beam 202, and thus the brightness of the electron beam 202 is enhanced. Due to the positive charge of the anode 216, the electron beam 202 is extracted. The Coulomb's compulsive force of the electrons in the electron beam 202 may be controlled by using the tunable aperture 218 which has different aperture sizes for limiting a width of the electron beam 202 by cutting away the unnecessary electrons outside the aperture. In order to condense the electron beam 202, the condenser 220 is applied to the electron beam 202, which also provides magnification. The condenser 220 shown in the FIG. 2 may e.g. be an electrostatic lens which can condense the electron beam 202. On the other hand, the condenser 220 may also be a magnetic lens or a combination of an electrostatic lens and magnetic lens.

The embodiment of the imaging system 240 as shown in FIG. 2B comprises a blanker, a set of apertures 242, a detector 244, four sets of deflectors 250, 252, 254, and 256, a pair of coils 262, a yoke 260, a filter, and an electrode 270. The electrode 270 is used to retard and deflect the electron beam 202, and further has electrostatic lens function. Besides, the coil 262 and the yoke 260 together constitute the magnetic objective lens. These components of the imaging system 240 may also be referred to as optics or electron optics in the remainder of this document.

The deflectors 250 and 256 are applied to scan the electron beam 202 to a large field of view, and the deflectors 252 and 254 are used for scanning the electron beam 202 to a small field of view. All the deflectors 250, 252, 254, and 256 may be used to control the scanning direction of the electron beam 202. The deflectors 250, 252, 254, and 256 may be electrostatic deflectors or magnetic deflectors.

FIG. 3 schematically depicts a possible control architecture of an EBI apparatus 100. As indicated in FIG. 1, the EBI apparatus comprises a load port 120, an object transfer system 130, a load/lock 150, an electron optics system 170 and a positioning device 180, e.g. including a z-stage 302 and an xy stage 305. As illustrated, these various components of the EBI apparatus may be equipped with respective controllers, i.e., an object transfer system controller 310 connected to the object transfer system 130, a load/lock controller 315, a stage controller 320, a detector controller 320 (for control of detector 244) and an electron optics (EU) controller 325. These controllers may e.g. be communicatively connected to a system controller computer 335 and an image processing computer 340, e.g. via a communication bus 345. In the embodiment as shown, the system controller computer 335 and the image processing computer 340 may be connected to a workstation 350.

The load port 120 loads an object 190 (e.g., a wafer) to the object transfer system 130, and the object transfer system controller 310 controls the object transfer system 130 to transfer the object 190 to the load/lock 150. The load/lock controller 315 controls the load/lock 150 to the chamber 160, such that an object 190 that is to be examined can be fixed on a clamp (not shown), e.g. an electrostatic clamp, also referred to as an e-chuck. The positioning device, e.g. the z-stage 302 and the xy-stage 305, enable the object 190 to move under control of the stage controller 330. In an embodiment, a height of the z-stage 302 may e.g. be adjusted using a piezo component such as a piezo actuator. The electron optic controller 325 (in FIG. 3 also referred to as EU controller) may control all the conditions of the electron optics system 170, and the detector controller 320 may receive and convert the electric signals from the electro optic system (detector 244 in FIG. 2) into image signals. The system controller computer 335 is operable to send the commands to the corresponding controller. After receiving the image signals, the image processing computer 340 may process the image signals to identify defects.

In metrology devices, such as those described above, the object to be inspected is positioned accurately using a stage. The object to be inspected may be a glass or silicone substrate, or a wafer on which the structures have been exposed by a patterned beam or a reticle (also referred to as a mask or a a patterning device) for patterning a beam in a lithographic apparatus. The object to be inspected by the metrology devices may also be the reticle.

The stage for positioning the substrate in the metrology devices may be a glass substrate stage, a silicone substrate stage, a wafer stage, or a reticle stage. The stage may comprise at least one positioning device and a substrate support, which is supported and moved by such a positioning device. The positioning device may be configured, for example, to control the position of the substrate support with a positioning error less than 0.1 nm, 1 nm, 10 nm, 100 nm, or 1000 nm.

An electron beam generated in the EBI apparatus 100 and irradiated onto the substrate 300 may have different landing energies depending on the EBI apparatus settings. There are many different ways the landing energy in the EBI apparatus 100 may be determined and/or changed. One way of determining the landing energies of an electron beam is by supplying to the electron gun 210 a certain input voltage, generating an electron beam with a certain energy, irradiating the electron beam onto the substrate 300, and then decelerating the electron beam by the potential difference between the electron beam and the surface on which the electron beam is irradiated, e.g. the substrate 300 held on the substrate table. For example, the electron beam may be generated at a higher energy, for example keV, than its landing energy, for example 20 keV. The substrate table and/or the space around the substrate 300 held by the table may be negatively charged, for example between −1 kV and −50 kV, which results in the electron beam to be decelerated by the negative potential. As a result, the electrons in the electron beam, lose some energy before impinging on the substrate 300 with the required landing energy of 20 keV. Electrons in an electron beam with different landing energy typically focus at a different height when using the same electron optical system as described in later paragraphs, thus have different focus positions.

In some known EBI apparatus, the landing energy of the electrons in the electron beam is chosen to be a substantial nominal value. In such an EBI apparatus, there is typically a single nominal focus position for the EBI apparatus with a small variation of the focus which is used for image acquisition with the EBI apparatus 100. In these knowns apparatus, typically there are two example types of EBI apparatus: a low landing energy apparatus configured for acquiring an image with a low landing energy electron beam and a high landing energy apparatus configured for acquiring an image with a high landing energy electron beam.

The low landing energy inspection apparatus irradiates the substrate 300 with a low landing energy electron beam, for example about between 0.1 keV and 1 keV. The low landing energy inspection apparatus is typically used for high resolution inspection for detecting small features and/or defects, for example, in the order of nanometers such as 1000 nm, 100 nm, 10 nm, or 1 nm. However, as the technology advances, the possible resolution may be advanced even smaller.

The high landing energy inspection apparatus is configured to irradiate the substrate 300 with a high landing energy electron beam, for example about between 20 keV and 30 keV. The high landing energy apparatus typically is able to image and/or measure structures at a lower resolution than the low landing energy apparatus. However, using relatively high landing energy allows the electron to, at least partially, go through a top layer of the substrate 300 and may enable to measure a position of structures in different layers below the top layer and even measure a relative position of structures in different layers to each other, typically indicated as overlay measurements between layers.

Typically, high landing energy apparatus require a larger focus distance than the low landing energy apparatus when similar optics systems are used for the apparatus. For example, a high landing energy apparatus may require a focus distance of about 3 to 5 mm from the lowest optical element of the electron optics system while the low landing energy apparatus typically have a significantly smaller focus distance, for example, of about 100 um to 1 mm for a similar electron optics system.

When a single EBI apparatus is configured to operate for varying landing energies, for example, the high landing energy and the low landing energy as described above, the focus position of the EBI apparatus changes depending on the landing energy of the electron beam used. Thus, the EBI apparatus may be required to adapt for the focus position difference between the different landing energy operations (e.g. the high landing energy operation and the low landing energy operation). Besides the different landing energy operations as described above, small focus corrections, e.g. in the range of nanometers to micrometers may typically be done by either focus adjustment of the electron optics system 170, 200 of the EBI apparatus 100, or by moving the z stage of the EBI apparatus 100, which holds the substrate 300 (e.g. wafer or reticle), in z direction. However, the relatively large difference in the focus positions, for example, of about 3 to 5 mm between these operations is too large to be corrected in the same manner as the small focus correction.

One way of performing focus adjustments within the EBI apparatus 100 may be done by adjusting a focal length of one or more of the lenses of the electron optics system 170, 200 of the EBI apparatus 100, e.g. the objective lens. For example, when required to change a focal length of one of the (electro)magnetic lenses of the electron optics system 170, 200 typically an amplitude of the electric current running through the (electro)magnetic lens has to be changed. This different electric current typically causes a change of power dissipation inside the (electro)magnetic lens which typically results in a difference in heat production in the (electro)magnetic lens. This changed heat production typically influences the optical characteristics of the (electro)magnetic lens in a static and dynamic way of the EBI apparatus 100. One way of limiting this change in optical characteristics may be to adjust the cooling in the (electro)magnetic lens to substantially maintain the lens temperature. However, to adjust the cooling and to reach a new equilibrium which would allow users to acquire stable pictures with the EBI apparatus 100 typically takes a significant amount of time, during which the EBI apparatus 100 may be idle.

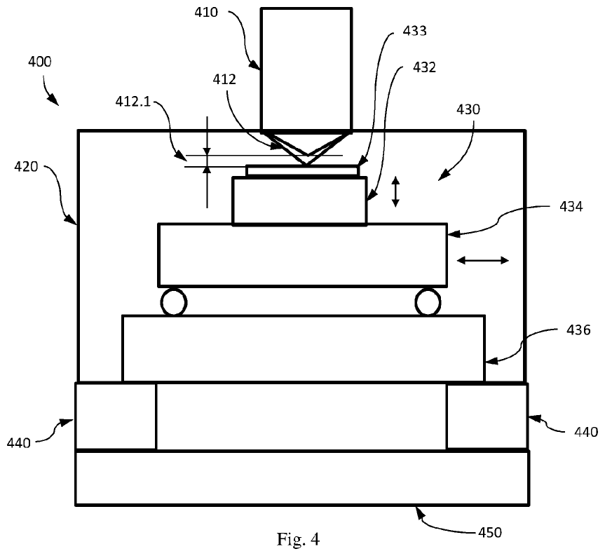

FIG. 4 schematically illustrate a known embodiment of an EBI apparatus 400 which may be configured to operate at varying landing energies. The EBI apparatus 400 contains the electron optics system 410, the vacuum chamber 420, the substrate stage 430, and the airmounts 440 to support the vacuum chamber 420 on the base plate 450. The substrate stage 430 contains the substrate table (not shown) to hold the substrate 433 and the fine z substrate stage 432. The substrate table is arranged on the fine z substrate stage 432. The fine z substrate stage 432 positions the substrate 433 along the optical axis of the Electron optics system 410, i.e. the z direction. The fine z substrate stage 432 adjusts the z position of the substrate 433 to position the substrate within the focus distance of the electron beam. The substrate stage 430 may further contain the xy-substrate stage 434 for positioning the substrate 433 in horizontal directions such that different locations on the substrate may be irradiate by the electron beam. The xy-substrate stage 434 may have a motion range of around several hundreds of millimeters, e.g. around 300 mm, 450 mm, or larger, The fine z substrate stage 432 may be arranged on the xy-substrate stage 434. The substrate stage 430 may be supported on the supporting plate 436 arranged inside the vacuum chamber 420.

In an embodiment, the substrate stage 430 may be supported directly on the inner wall of the vacuum chamber 420 (currently not shown). The airmounts 440 act as a vibration isolation system to reduce transfer of the floor vibration from the base plate 450 to the substrate 433. In the embodiment, the vacuum chamber 420, at least partially, supports the Electron optics system 410, possibly in combination with other supporting plate (not shown) that may be supported on the same base plate 450 or may also possibly be on a different base. In operation, the Electron beam are generated by the Electron optics system 410 and irradiated into the vacuum chamber 420. The electron beam is directed onto the substrate 433. The secondary electrons emanating from the substrate 433 as a result of the irradiate electron beam are detected by the detector (not shown) to obtain images of the substrate. The electron beam using the EBI apparatus as described in FIG. 4 focuses on different focus distances depending on the landing energy of the electron beam. As described above, for example, the electron beam with the high landing energy may focus about 3 to 5 mm from the lowest optical element of the electron optics system while the electron beam with the low landing energy may focus about 100 um to 1 mm from the lowest optical element. Thus, the focus distance of the electron beam may varies, for example, around between 3 to 5 mm within the EBI apparatus depending on the landing energy of the electron beam.

In the known devices described above, the fine z substrate stage 432 may have a motion range of 1000 micrometers or smaller. Thus, such fine z substrate stage 432 is not capable to position the substrate over 3 to 5 mm such that the substrate may be positioned within the focus of the electron beam of both the high landing energy and the low landing energy operations.

Therefore, to cope with the change of the focus distance of the electron beam, the focus of the Electron optics system 410 is required to be adjusted. However, such change of the focus distance of the Electron optics system 410 causes the temperature change of the Electron optics system and causes the EBI apparatus a significant downtime until the Electron optics system is stabilized.

It is thus an objective of the embodiments shown hereinafter to provide a solution for an electron beam inspection apparatus having a relatively large range of landing energies to position the substrate within the focus range of the electron beam inspection apparatus. As such, a single electron beam inspection apparatus may be used efficiently at the relatively large range of landing energies while preventing long stabilizing times.

To avoid this idle time, the EBI apparatus 100 according to the embodiments described hereinafter comprise an additional z positioning device for positioning the substrate 300 or the chamber 420 over a relatively long distance along the optical axis of the electron optics system 170, 200, (further also indicated as the z-axis) to at least partially compensate for the difference in focus position due to the difference in landing energy. Such additional z positioning device allows a user to move the substrate 300 to within the focus range of the electron beam and to adapt to variations of the focus range due to, e.g. variations of the landing energy, etc.

According to a first aspect of the embodiments, the substrate is moved by the additional zpositioning device to adjust the relative position between the substrate and the electron optics system. As indicated already above, a change of the operational mode of the electron beam inspection apparatus from the relatively high landing energy operation to the relatively low landing energy operation, or vice versa, typically results in the shift of the focal distance of the electron beam inspection apparatus of about 3 to 5 mm in the z-direction (i.e. the direction of the optical axis of the SEM). This difference of the focus distances of about 3 to 5 mm is larger than known fine z substrate stage 432 in EBI apparatus.

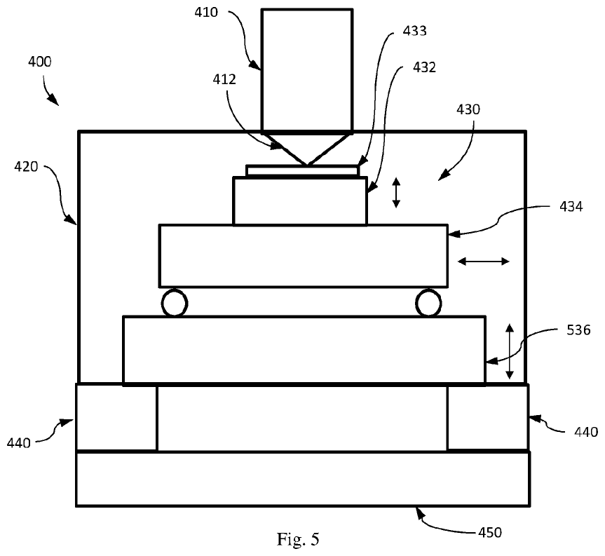

In an embodiment of the charged electron beam inspection apparatus, the z substrate stage may comprises a fine z stage and the additional z positioning device, which is a coarse z substrate stage, as shown in FIG. 5. The EBI apparatus of FIG. 5 contains mostly the same components and arranged in the same configuration as in FIG. 4 unless otherwise stated. The fine z substrate stage 432 may be configured to position the substrate with a higher accuracy, for example, in the order of nanometers such as 100 nm, 10 nm, 1 nm, 0.1 nm, or smaller. The coarse z substrate stage 536 may be configured to position the substrate with a lower accuracy than the fine stage, for example, in the order of micrometers such as 1000 micrometers, 100 micrometers, 10 micrometers, 1 micrometers, 0.1 micrometers, or smaller. The fine z substrate stage 432 may, for example, be configured to have a motion range of around 1000 micrometers, 100 micrometers, 10 micrometers, or smaller. The coarse z substrate stage 536 may, for example, be configured to have a motion range of around several millimeters, e.g. around 3 to 5 mm or larger. The fine z substrate stage 432 may, for example, be used for the fine focus adjustment in use when operating on one landing energy and the coarse z substrate stage 536 may, for example, be used to adjust for the focus adjustment when changing between the high and low landing energy operations.

The fine z substrate stage 432 may, for example, be mounted on the coarse z substrate stage 536 and the coarse z substrate stage 536 may be mounted on the xy-substrate stage 434. Alternatively, an existing substrate stage comprising the fine z substrate stage 432 and, optionally, x,y substrate stage 434 may be placed on the coarse z substrate stage 536 as shown in FIG. 5.

The coarse z substrate stage 536 has a z motion range which is at least the same or longer than the focus difference between the high landing energy operation and the low landing energy operation, bringing the apparatus in either one of the focus modes. If needed, measures may be taken to avoid undesired tilt of the substrate 443 e.g. by proper guiding (roller bearings, sliding bearing, leaf springs, etc.).

The coarse z substrate stage 536 may be a lifting device realized by different mechanisms: cam-shaft mechanism, a bellow actuator, a piezo stack, piezoelectric fingers, reluctance actuators, a spindle, a ball-screw mechanism, or a lever mechanism. These mechanisms are given by way of example and the embodiment is not limited to these particular mechanisms. These lifting devices may further be configured to position the substrate 433, the fine z substrate stage 432 and/or the xy-substrate stage 434 at a plurality of fixed positions. The fixed positions may be a limited number of positions lager than 1, e.g. 2, 3, 4, or more.

According to a second aspect of the embodiments, the z position of the electron optics system may be controlled by the additional z positioning device to adjust a relative position of the substrate to at or near to the focal point of the electron beam inspection apparatus, such that the electron beam focuses on the substrate. As such the change of the relative position of the substrate may compensate for the change in the focal length after the operational mode of the electron beam inspection apparatus has been changed, e.g. from the high landing energy operation mode to the low landing energy operation mode, or vice versa.

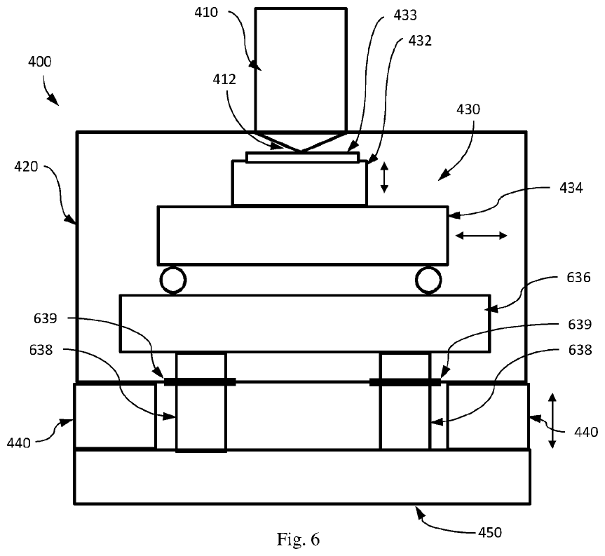

FIG. 6 shows an example embodiment of the EBI apparatus according to the second aspect of the embodiments. The EBI apparatus of FIG. 6 contains mostly the same components and arranged in the same configuration as in FIG. 4 unless otherwise stated. In this embodiment, the Electron optics system 410 may at least partially be supported by a vacuum chamber 420 which, in operation, contains the substrate 433 to be inspected and the substrate stage 430. In use, the electron beam is generated by the Electron optics system 410 and is guided into the vacuum chamber 420 to be irradiated into the substrate 433. In such a configuration, the z position of the vacuum chamber 420 may, for example, be controlled to adjust the relative distance between the lowest optical element the Electron optics system 410 and the substrate 433 when the focal length changes due to a switch from the high landing energy operation to the low landing energy operation, or vice versa. In this embodiment, it is required that the substrate 433 and the substrate stage 430 including the fine z substrate stage 432 are not supported by the vacuum chamber 420 but are supported by a separate intermediate frame 636, also referred to as frame, which is not connected to the vacuum chamber 420. When the vacuum chamber 420 is moved in the z direction, the Electron optics system 410 also moves in the z direction while the z position of the substrate 433 and the fine z substrate stage 432 do not change. The intermediate frame 636 may be supported by connecting rods 638. These connecting rods 638 may, for example, extend through the vacuum chamber 420 via (vacuum tight) apertures 639 and may connect to the base plate 450. Alternatively, the intermediate frame 636 may be supported on a separate base plate (not shown) not connected to the base plate 450 supporting the vacuum chamber 420 via the airmounts 440. The apertures 639 for the connecting rods 638 may have seals such that the air leakage through the seals into the vacuum chamber 420 is avoided.

The additional z positioning device may comprise a z actuator 442, e.g. a bellow actuator, arranged to move the vacuum chamber height as shown in FIG. 6. Alternatively, or in addition, the vacuum chamber may be supported and actuated by air mounts 440 such that the z position of the vacuum chamber 420, and thus the Electron optics system 410, may be adjusted by adjusting the air mount height (In this case, the additional z positioning device comprises the air mounts 440 instead of or in addition to the z actuator 442). Thus, the fine focus adjustment may be performed using the fine z substrate stage 432 inside the vacuum chamber 420 and the coarse focus adjustment for the focus change, for example, due to the change of the landing energy may be adjusted by controlling the vacuum chamber z position.

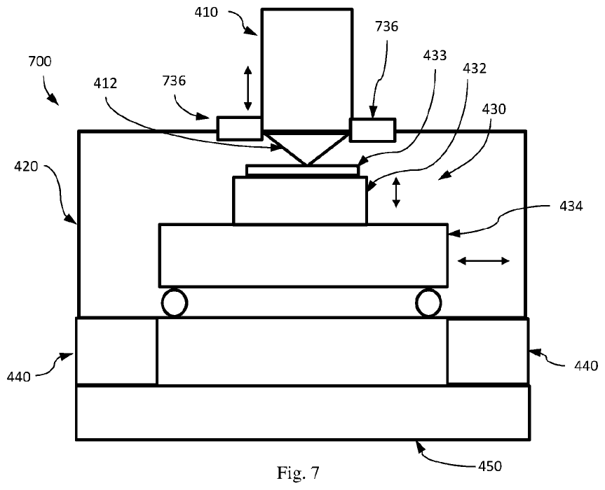

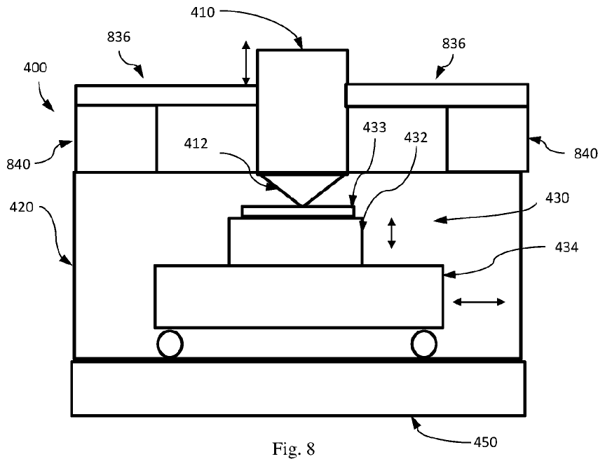

FIG. 7 shows an example embodiment of the EBI apparatus according to the third aspect of the embodiments. The EBI apparatus of FIG. 7 contains mostly the same components and arranged in the same configuration as in FIG. 4 unless otherwise stated. In this embodiment, the Electron optics system 410 may at least partially be supported by a vacuum chamber 420 which, in operation, contains the substrate 433 to be inspected and the substrate stage 430. In such an embodiment, the substrate stage may be supported on the supporting plate 436 (not shown) or supported directly on the bottom side inner surface of the vacuum chamber as shown in FIG. 7. In use, the electron beam is generated by the Electron optics system 410 and is guided into the vacuum chamber 420 to be irradiated into the substrate 433. In such a configuration, the z position of the Electron optics system 410 may, for example, be controlled to adjust the relative distance between the lowest optical element the Electron optics system 410 and the substrate 433 when the focal length changes due to a switch from the high landing energy operation to the low landing energy operation, or vice versa. For example, the actuators 736 may be arranged between the vacuum chamber 420 and the Electron optics system 410. These actuators 736 may be located around the Electron optics system 410 not to block/interfere the electron beam(s) generated by the Electron optics system 410. Several isolated lifting elements, for example, 1, 2, 3, 4, or more, or a common lifting ring could be used to lift the Electron optics system 410. A bellow is then needed to seal off the vacuum chamber. Advantage of lifting the Electron optics system 410 instead of the substrate stage 434 is that the EBI apparatus 700 requires a minimum amount of modification to its design from the EBI apparatus 400 without the functionality of controlling the relative distance between the lowest optical element the Electron optics system 410 and the substrate 433.

FIG. 8 shows an example embodiment of the EBI apparatus according to the fourth aspect of the embodiments. The EBI apparatus of FIG. 8 contains mostly the same components and arranged in the same configuration as in FIG. 7 unless otherwise stated. In this embodiment, the relative distance between the lowest optical element the Electron optics system 410 and the substrate 433 may also be controlled by the actuator 836. In this embodiment, the air mount 840 may be mounted on the vacuum chamber 420 and the actuators 836 may be supported by the air mount 840 to actuate the Electron optics system 410 in the z-direction.

In all the aspects and embodiments described above, the change of the focus distance between the relatively high landing energy operation and the relatively low landing energy operation may be adjusted by adjusting the relative distance between the Electron optics system and the substrate along the optical axis. In this way, a single EBI apparatus may be used for a relatively large range of landing energies while avoiding long idle times of the apparatus for switching between different operations of the EBI apparatus with different nominal landing energies.

Above embodiments describe the focus distance adjustment of an EBI apparatus for relatively large varying landing energy operations with a single beam electron beam apparatus. The same solutions may be applicable to multi-beam electron beam apparatus as well. When a single nominal landing energy is chosen for the multiple electron beams generated by the multi-beam electron beam apparatus, the focus distance of the electron beams varies in a similar manner as the electron beam of the single beam electron beam apparatus. Therefore, the same solution as the above described embodiments may be applicable to multi-beam electron beam apparatus as well.

Although the embodiments above are described for the electron beam apparatus, similar solutions are applicable to other charged particle beam apparatus. For example, ion beam apparatus containing the ion beam generator for generating the ion beam, the ion beam optics system for projecting the ion beam onto the substrate may implement the described embodiments in this document. Similarly, the embodiments of this documents may be applied for charged particle beam apparatus in general that contains the particle beam generator for generating the particle beam and the particle beam optics system, also referred to as optics, for projecting the charged particle beam on the substrate.

Further embodiments may be described in the following clauses:

1. A charged particle apparatus comprising:
a particle beam generator configured for generating a particle beam to be irradiated onto a substrate;
optics configured for focusing the particle beam;
a first positioning device configured for positioning the substrate relative to the particle beam generator along an optical axis of the particle beam generator over a first range of movement;
a second positioning device configured for positioning the substrate relative to the particle beam generator along the optical axis; and
a controller configured for switching between a first operational mode and a second operational mode of the apparatus, the apparatus being configured, when operating in the first operational mode, for irradiating the substrate by the particle beam at a first landing energy of the particle beam, and the apparatus being further configured, when operating in the second operational mode, for irradiating the substrate with the particle beam at a second landing energy of the particle beam, the second landing energy being different from the first landing energy;
wherein, when operating in the first operational mode, the second positioning device is configured to position the substrate relative to the particle beam generator at a first focus position of the particle beam, and
wherein, when operating in the second operational mode, the second positioning device is configured to position the substrate relative to the particle beam generator at a second focus position of the particle beam, the second focus position being at a distance from the first focus position, the distance being larger than the first range of movement.

2. The charged particle beam apparatus according to clause 1, further comprising:
a chamber configured to at least partially support the particle beam generator, the substrate being arranged inside the chamber;
wherein the second positioning device is arranged inside the chamber and is configured to position the substrate with respect to the particle beam generator along the optical axis by moving the first positioning device.

3. The charged particle beam apparatus according to clause 1 or 2, wherein the first positioning device comprises a fine positioning device and the second positioning device comprises a coarse positioning device, wherein the fine positioning device is configured for positioning the substrate with a higher accuracy than the coarse positioning device.

4. The charged particle beam apparatus according to any of the preceding clauses, wherein the second positioning device is one of a cam-shaft mechanism, bellow actuator, piezo stack, piezoelectric finger, reluctance actuator, spindle, ball-screw mechanism, and lever mechanism.

5. The charged particle beam apparatus according to clause 1, further comprising:
a chamber configured to at least partially support the particle beam generator, the substrate being arranged inside the chamber,
wherein the apparatus further comprises a frame configured for supporting the first positioning device, the frame not being connected to the chamber; and
wherein the second positioning device is arranged outside the chamber and is configured to position the substrate with respect to the particle beam generator along the optical axis by moving the chamber.

6. The charged particle beam apparatus according to clause 5, wherein the second positioning device comprises a bellow actuator or an airmount.

7. The charged particle beam apparatus according to any preceding clauses, wherein the second positioning device is configured to position the substrate to one of a plurality of fixed positions.

8. The charged particle beam apparatus according to clause 7, wherein the plurality of fixed positions comprises a limited number of positions.

9. The charged particle beam apparatus according to clause 8, wherein the limited number of positions is larger than 1.

10. The charged particle beam apparatus according to clause 9, wherein the limited number of positions is 2.

11. The charged particle beam apparatus according to clause 1, wherein the second positioning device is configured to position the particle beam generator with respect to the substrate along the optical axis by moving the particle beam generator.

12. The charged particle beam apparatus according to clause 11, further comprising a chamber configured to at least partially support the particle beam generator, the substrate being arranged inside the chamber; wherein the second positioning device is arranged on the chamber.

13. The charged particle beam apparatus according to clause 12, wherein the second positioning device is arranged on the chamber via an air mount.

14. The charged particle beam apparatus according to any preceding clauses, wherein the particle beam comprises an electron beam, the particle beam generator comprises an electron beam generator, and the optics comprises an electron optics system.

15. The charged particle beam apparatus according to any of clause 1 to 14, wherein the particle beam comprises an ion beam, the particle beam generator comprises an ion beam generator, and the optics comprises an ion beam optics system.

16. The charged particle beam apparatus according to any of clause 1 to 14, wherein particle beam comprises an electron beam apparatus, a scanning electron microscope, an electron beam direct writer, an electron beam projection lithography apparatus, an electron beam inspection apparatus, an electron beam defect verification apparatus, an electron beam metrology apparatus, a lithographic apparatus, or a metrology apparatus.

The terms “radiation” and “beam” used in relation to the lithographic apparatus encompass all types of electromagnetic radiation, including ultraviolet (UV) radiation (e.g., having a wavelength of or about 365, 355, 248, 193, 157 or 126 nm) and extreme ultra-violet (EUV) radiation (e.g., having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

The foregoing description of the specific embodiments will so fully reveal the general nature of the embodiments that others can, by applying knowledge within the skill of the art, readily modify and/or adapt for various applications such specific embodiments, without undue experimentation, without departing from the general concept of the present embodiments. Therefore, such adaptations and modifications are intended to be within the meaning and range of equivalents of the disclosed embodiments, based on the teaching and guidance presented herein. It is to be understood that the phraseology or terminology herein is for the purpose of description by example, and not of limitation, such that the terminology or phraseology of the present specification is to be interpreted by the skilled artisan in light of the teachings and guidance.

Specific orientations have been given when describing the relative arrangement of components. It will be appreciated that these orientations are given purely as examples and are not intended to be limiting. For example, the xy-stage of the positioning device 180 has been described as being operable to position an object in a substantially horizontal plane. The xy-stage of the positioning device 180 may alternatively be operable to position an object in a vertical plane or in an oblique plane. Orientations of components may vary from the orientations described herein whilst maintaining their intended functional effect of said components.

Although specific reference may be made in this text to embodiments of the invention in the context of an inspection apparatus, the object table may be suitable for use in: an electron beam apparatus, a scanning electron microscope, an electron beam direct writer, an electron beam projection lithography apparatus, an electron beam inspection apparatus, an electron beam defect verification apparatus, or an electron beam metrology apparatus.

The breadth and scope of the present embodiments should not be limited by any of the above-described exemplary embodiments, but should be defined only in accordance with the following claims and their equivalents.

1. A charged particle apparatus comprising:
a particle beam generator configured for generating a particle beam to be irradiated onto a substrate;
optics configured for focusing the particle beam;
a first positioning device configured for positioning the substrate relative to the particle beam generator along an optical axis of the particle beam generator over a first range of movement;
a second positioning device configured for positioning the substrate relative to the particle beam generator along the optical axis; and
a controller configured for switching between a first operational mode and a second operational mode of the apparatus, the apparatus being configured, when operating in the first operational mode, for irradiating the substrate by the particle beam at a first landing energy of the particle beam, and the apparatus being further configured, when operating in the second operational mode, for irradiating the substrate with the particle beam at a second landing energy of the particle beam, the second landing energy being different from the first landing energy;
wherein, when operating in the first operational mode, the second positioning device is configured to position the substrate relative to the particle beam generator at a first focus position of the particle beam, and
wherein, when operating in the second operational mode, the second positioning device is configured to position the substrate relative to the particle beam generator at a second focus position of the particle beam, the second focus position being at a distance from the first focus position, the distance being larger than the first range of movement.

2. The charged particle beam apparatus according to claim 1, further comprising:
a chamber configured to at least partially support the particle beam generator, the substrate being arranged inside the chamber;
wherein the second positioning device is arranged inside the chamber and is configured to position the substrate with respect to the particle beam generator along the optical axis by moving the first positioning device.

3. The charged particle beam apparatus according to claim 1, wherein the first positioning device comprises a fine positioning device and the second positioning device comprises a coarse positioning device, wherein the fine positioning device is configured for positioning the substrate with a higher accuracy than the coarse positioning device.

4. The charged particle beam apparatus according to claim 1, wherein the second positioning device is one of a cam-shaft mechanism, bellow actuator, piezo stack, piezoelectric finger, reluctance actuator, spindle, ball-screw mechanism, and lever mechanism.

5. The charged particle beam apparatus according to claim 1, further comprising:
a chamber configured to at least partially support the particle beam generator, the substrate being arranged inside the chamber,
wherein the apparatus further comprises a frame configured for supporting the first positioning device, the frame not being connected to the chamber; and
wherein the second positioning device is arranged outside the chamber and is configured to position the substrate with respect to the particle beam generator along the optical axis by moving the chamber.

6. The charged particle beam apparatus according to claim 5, wherein the second positioning device comprises a bellow actuator or an airmount.

7. The charged particle beam apparatus according to claim 1, wherein the second positioning device is configured to position the substrate to one of a plurality of fixed positions.

8. The charged particle beam apparatus according to claim 7, wherein the plurality of fixed positions comprises a limited number of positions.

9. The charged particle beam apparatus according to claim 8, wherein the limited number of positions is larger than 1.

10. The charged particle beam apparatus according to claim 9, wherein the limited number of positions is 2.

11. The charged particle beam apparatus according to claim 1, wherein the second positioning device is configured to position the particle beam generator with respect to the substrate along the optical axis by moving the particle beam generator.

12. The charged particle beam apparatus according to claim 11, further comprising a chamber configured to at least partially support the particle beam generator, the substrate being arranged inside the chamber; wherein the second positioning device is arranged on the chamber or is arranged on the chamber via an air mount.

13. The charged particle beam apparatus according to claim 1, wherein the particle beam comprises an electron beam, the particle beam generator comprises an electron beam generator, and the optics comprises an electron optics system.

14. The charged particle beam apparatus according to claim 1, wherein the particle beam comprises an ion beam, the particle beam generator comprises an ion beam generator, and the optics comprises an ion beam optics system.

15. The charged particle beam apparatus according to claim 1, wherein particle beam comprises an electron beam apparatus, a scanning electron microscope, an electron beam direct writer, an electron beam projection lithography apparatus, an electron beam inspection apparatus, an electron beam defect verification apparatus, an electron beam metrology apparatus, a lithographic apparatus, or a metrology apparatus.
